(19) United States
(12) Patent Application Publication
(10) Pub. No.: US 2009/0208707 A1
(43) Pub. Date: Aug. 20, 2009

(54) THIN FILM FORMING METHOD AND LAYERED STRUCTURE OF THIN FILM

(75) Inventors: Hirokazu Ueda, Hyogo (JP); Toshihisa Nozawa, Hyogo (JP)

Correspondence Address: PEARNE & GORDON LLP, 1801 EAST 9TH STREET, SUITE 1200, CLEVELAND, OH, 44114-3108, US

(73) Assignee: TOKYO ELECTRON LIMITED, Tokyo (JP)

(21) Appl. No.: 12/305,226

(22) PCT Filed: Oct. 4, 2007
(86) PCT No.: PCT/JP2007/069487

§ 371 Date: Dec. 17, 2008

(30) Foreign Application Priority Data
Oct. 11, 2006 (JP) 2006-277967

(51) Int. Cl. B32B 3/10; C23C 14/34; B32B 9/00; B32B 15/04

(52) U.S. Cl. 428/172; 204/192.15; 428/698

(57) ABSTRACT

Disclosed is a thin film forming method including: a prevention film forming process for forming a charging damage prevention film for preventing a charging damage on a surface of a target object by a sputtering; and a thin film forming process for forming a desired thin film on a surface of the charging damage prevention film, which is formed on the surface of the target object, by a sputtering.

### TECHNICAL FIELD

The present invention relates to a thin film forming method in case of forming a barrier film, a seed film or the like on a target object such as a semiconductor wafer, and also relates to a layered structure of thin films.

### BACKGROUND ART

Generally, in order to manufacture a semiconductor device, various processes such as a film forming process, a pattern etching process and the like are performed on a semiconductor wafer repeatedly, whereby a desired device is manufactured. Recently, a line width or a hole diameter is getting gradually miniaturized pursuant to an increasing demand for a high-integrated and high-miniaturized semiconductor device.

As a wiring material or a burying material, aluminum or an aluminum alloy has been generally used. Recently, since it is needed to lessen an electrical resistance according to the miniaturization of various kinds of dimensions, there is a tendency to use tungsten or copper as the wiring material or the burying material because they have a very low electrical resistance and a low price (see, for example, Japanese Patent Laid-open Publication No. 2000-77365, Japanese Patent Laid-open Publication No. H10-74760, Japanese Patent Laid-open Publication No. H10-214836 and Japanese Patent Laid-open Publication No. 2005-285820).

When aluminum (including an Al alloy), tungsten (W), copper (Cu) or the like is used as the wiring material, a barrier layer is generally formed as a base film prior to forming the wiring material in order to prevent the wiring material itself from being silicided and to improve adhesivity with a base layer. When the aluminum (including the Al alloy) or tungsten is used as the wiring material, a Ti film or a TiN film is used as the barrier layer. Meanwhile, when the copper is used as the wiring material, a Ta film, a TaN film or the like is used. Various kinds of thin films to be used as the barrier layer are formed by an optimal film forming method selected among a thermal CVD (Chemical Vapor Deposition) method, a plasma CVD method, a sputtering method and the like depending on the kind of film.

However, besides the thermal CVD method, the plasma CVD method or the sputtering method can be used as the film forming method, if possible. In case of using the plasma CVD method, a wafer itself is likely to be electrically charged during the film formation, and as a result, there is a likelihood of an occurrence of a charging damage such as a breakdown of an insulating film, or the like. Therefore, depending on the kind of film, there is a tendency to use the sputtering method in which the charging of the wafer itself is relatively difficult to occur.

Here, an example of the film formation by the sputtering method as described above will be explained. FIGS. 6A and 6B provide explanatory diagrams to describe an example of a conventional film forming method by using the sputtering method. As illustrated in FIG. 6A, an insulating layer 2 made of, e.g., a SiO₂ film or the like is formed on a surface of a semiconductor wafer S. A recess 4 of a hole shape such as a via hole, a through hole or a contact hole is formed in the insulating layer 2. A contact portion 6 of an under layer to be electrically connected is exposed at a bottom portion of the recess 4. The contact portion 6 corresponds to a wiring layer in the under layer or an electrode of a device in the under layer, e.g., a source or a drain of a transistor, or the like.

During the film formation, as illustrated in FIG. 6B, a Ti film, for example, is nearly uniformly formed on the surface of the wafer S including an inner surface of the recess 4 by the sputtering method. Then, a TiN film 10 is nearly uniformly formed on the surface of the preformed Ti film 8 by the sputtering method again. Accordingly, there is formed a barrier layer 12 made up of a layered structure of the Ti film 8 and the TiN film 10.

After the barrier layer 12 is formed, a film of a wiring material 14 is formed by, e.g., the thermal CVD method, whereby the inside of the recess 4 is filled and the wiring layer 14 is formed on the entire upper surface of the wafer S. The wiring layer 14 is made of, e.g., aluminum (including an aluminum alloy), tungsten or the like. Then, the wiring layer 14 or the barrier layer 12 is etched into a desired pattern, so that a desired wiring pattern is formed.

### DISCLOSURE OF THE INVENTION

In a film forming method using the above-described sputtering method, the incidence rate of a charging damage decreases remarkably. Nonetheless, the charging damage may be incurred depending on situations. If the charging damage is incurred, it may result in a degradation of characteristics or reliability of the semiconductor device. In particular, a degradation of transistor characteristics may cause a problem such as an increase in power consumption, a decrease in an operating speed, or the like.

The present invention has been conceived to solve the foregoing problems efficiently. The purpose of the present invention is to provide a thin film forming method capable of sharply reducing a generation of a charging damage during the sputtering.

In accordance with the present invention, there is provided a thin film forming method including: a prevention film forming process for forming a charging damage prevention film for preventing a charging damage on a surface of a target object by a sputtering; and a thin film forming process for forming a desired thin film on a surface of the charging damage prevention film, which is formed on the surface of the target object, by a sputtering.

In accordance with the present invention, when forming the desired thin film on the surface of the target object by the sputtering, the charging damage prevention film is formed in advance by the sputtering as a pre-process. Accordingly, it is possible to sharply reduce an occurrence of the charging damage during the sputtering.

Desirably, the charging damage prevention film is made of one of Co (cobalt), Ge (germanium) and Ru (ruthenium).

Further, desirably, on the surface of the target object, an insulating layer is formed in advance, and in the prevention film forming process, the charging damage prevention film for preventing the charging damage is formed on a surface of the insulating layer.

In addition, for example, in the thin film forming process, one kind of thin film is formed. Furthermore, for example, in the thin film forming process, a plurality of different kinds of thin films is formed in sequence.

Moreover, it is desirable that the thin film is a metal film or a metal-containing film.

Further, in accordance with the present invention, there is provided a layered structure of thin films formed on a surface of a target object, the structure including: a charging damage prevention film formed on the surface of the target object by a sputtering; and a single-layered thin film formed on a surface of the charging damage prevention film by a sputtering.

Desirably, the single-layered thin film is made of a TiN film. For example, the TiN film constitutes a barrier layer. Further, for example, on the TiN film, a wiring layer is formed. The wiring layer is made of, for example, one of an Al (including an Al alloy) film, a W film and a Cu film.

Furthermore, in accordance with the present invention, there is provided a layered structure of thin films formed on a surface of a target object, the structure including: a charging damage prevention film formed on the surface of the target object by a sputtering; and a plurality of thin film elements formed on a surface of the charging damage prevention film by a sputtering.

Desirably, the plurality of thin film elements are of different kinds from one another. For example, the plurality of thin film elements are made of a Ti film element in a lower layer and a TiN film element in an upper layer. In addition, for example, the plurality of thin film elements may be made of a TaN film element in a lower layer and a Ta film element in an upper layer. Further, for example, the plurality of thin film elements constitute a barrier layer. Furthermore, for example, on the plurality of thin film elements, a wiring layer is formed. The wiring layer is made of, for example, one of an Al (including an Al alloy) film, a W film and a Cu film.

### BRIEF DESCRIPTION OF THE DRAWINGS

FIG. 1 is a cross sectional view showing an example of a plasma film forming apparatus for performing a thin film forming method in accordance with the present invention;

FIGS. 2A to 2C are cross sectional views each showing an example of a layered structure of thin films formed in accordance with each embodiment of the present invention;

FIG. 3 is a flowchart to describe each embodiment of the present invention;

FIG. 4 is a graph showing an occurrence or nonoccurrence of a charging damage;

FIG. 5 is a plane view showing an antenna structure of an antenna substrate called a TEG; and

FIGS. 6A and 6B are explanatory diagrams to show an example of a conventional film forming method using a sputtering method.

### BEST MODE FOR CARRYING OUT THE INVENTION

Hereinafter, a film forming method and a layered structure of thin films in accordance with embodiments of the present invention will be described in detail with reference to the accompanying drawings.

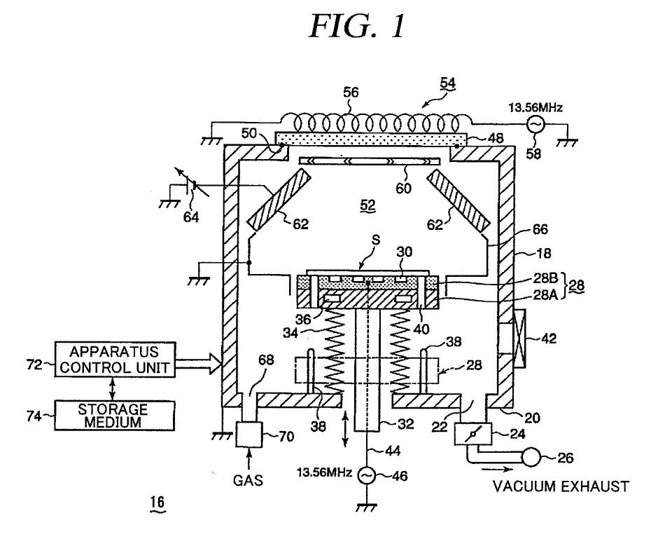

FIG. 1 is a cross sectional view showing an example of a plasma film forming apparatus for performing the thin film forming method in accordance with the present invention. Here, ICP (Inductively Coupled Plasma) type plasma sputtering apparatus is exemplified as a plasma film forming apparatus. As illustrated in FIG. 1, the plasma film forming apparatus 16 includes a processing vessel 18 formed of, e.g., aluminum or the like in a cylindrical shape. The processing vessel 18 is grounded and a gas exhaust port 22 is formed in a bottom portion 20 thereof. The gas exhaust port 22 is connected with a vacuum pump 26 via a throttle valve 24 for performing a pressure control such that the inside of the processing vessel 18 can be vacuum-evacuated.

Inside the processing vessel 18, there is installed a mounting table 28 of a circular plate shape. The mounting table 28 includes a mounting table main body 28A made of, e.g., aluminum and an electrostatic chuck 28B installed on a top surface thereof. A semiconductor wafer S, which is a target object, can be attracted onto the electrostatic chuck 28B to be held thereon. Further, in a top surface of the electrostatic chuck 28B, there is formed a gas groove 30 through which a thermally conductive gas is flown. When necessary, the thermally conductive gas such as an Ar gas or the like is supplied to the gas groove 30 to improve a thermal conductivity between the wafer S and the mounting table 28. Further, a non-illustrated DC voltage for attraction is applied to the electrostatic chuck 28B when necessary.

The mounting table 28 is supported by a supporting column 32 extending downward from a center portion of a bottom surface of the mounting table 28. A lower portion of the supporting column 32 passes through the bottom portion 20 of the processing vessel 18. Further, the supporting column 32 is movable up and down by a non-illustrated elevating mechanism, whereby it is possible to move the mounting table 28 up and down.

Further, a metal bellows 34 in the shape of an expansible and contractible bellows is installed to surround the supporting column 32. An upper end of the metal bellows 34 is airtightly coupled to the bottom surface of the mounting table 28 while a lower end of the metal bellows 34 is airtightly coupled to a top surface of the bottom portion 20 of the processing vessel 18. With this configuration, it is possible to move the mounting table 28 up and down while maintaining the airtightness inside the processing vessel 18. In the mounting table main body 28A of the mounting table 28, there is formed a coolant circulation path 36 through which a coolant for cooling the wafer S is flown. The coolant is supplied and discharged through a non-illustrated flow path in the supporting column 32.

Uprightly installed on the vessel bottom portion 20 to be upwardly extended therefrom are, e.g., three supporting pins 38 (only two are illustrated in the drawing). Further, corresponding to these supporting pins 38, pin insertion through holes 40 are formed in the mounting table 28. With this configuration, when the mounting table 28 descends, upper end portions of the supporting pins 38 passing through the pin insertion through holes 40 receive the wafer S thereon, thus carrying out a transfer of the wafer S with respect to a non-illustrated transfer arm which is inserted from the exterior. In a lower sidewall of the processing vessel 18, there is installed a gate valve 42 configured to be opened and closed through which the transfer arm can be inserted.

Further, the electrostatic chuck 28B installed on the mounting table main body 28A is connected with a bias power supply 46 having a high frequency power supply for generating a high frequency wave of, e.g., about 13.56 MHz, via a wiring 44. With this configuration, a predetermined bias power can be applied to the mounting table 28. Further, the bias power supply 46 can vary its output bias power as required.

Meanwhile, in a ceiling portion of the processing vessel 18, a transmission plate 48 made of a dielectric material such as aluminum oxide or the like transmitting the high frequency wave is airtightly installed via a sealing member 50 such as an O-ring. Further, in the opposite side of a processing space 52 of the processing vessel 18 with respect to the transmission plate 48, there is installed a plasma generating source 54 for generating plasma by converting a plasma excitation gas such as an Ar gas into the plasma. Further, it may be possible to use other inactive gases, e.g., He, Ne or the like as the plasma excitation gas instead of the Ar gas. To be specific, the plasma generating source 54 may include an induction coil 56 installed on the transmission plate 48. The induction coil 56 is connected with a high frequency power supply 58 of, e.g., about 13.56 MHz for generating the plasma so that it is possible to introduce a high frequency wave into the processing space 52 via the transmission plate 48. Further, the plasma power outputted from the high frequency power supply 58 can be varied as required.

Further, right under the transmission plate 48, there is installed a baffle plate 60 made of, e.g., aluminum for diffusing the introduced high frequency wave. Further, installed underneath the baffle plate 60 so as to surround an upper portion of the processing space 52 is a metal target 62 of, e.g., a ring shape having a cross section slanted inwardly (i.e., having an empty circular truncated cone shape). The metal target 62 is connected with a DC power supply 64 for supplying a discharging power to the metal target 62. It may be possible to use an AC power supply instead of the DC power supply 64. Here, a DC power outputted from the DC power supply 64 can be varied as required. Further, here, it may be possible to use, e.g., cobalt, titan, tantalum, copper or the like as the metal target 62 depending on the kinds of films to be formed. These metals are sputtered into metal atoms or metal atom groups by Ar ions in the plasma. Further, most of the sputtered metal atoms or metal atom groups are ionized while passing through the plasma. Moreover, titan or tantalum is used to form a barrier layer, and copper is used to form a seeding film.

Further, a cylindrical protection cover 66 made of, e.g., aluminum is installed under the metal target 62 so as to surround the processing space 52. The protection cover 66 is grounded. Further, a lower portion of the protection cover 66 is bent inward to be positioned near a lateral portion of the mounting table 28.

Further, in the bottom portion of the processing vessel 18, there is installed a gas inlet opening 68 serving as a gas introducing means for introducing a predetermined necessary gas into the processing vessel 18. A rare gas such as the Ar gas used as the plasma excitation gas or other necessary gases such as an N₂ gas or the like are introduced from the gas inlet opening 68 via a gas control unit 70 including a gas flow rate controller, a valve and the like.

Further, each component of the film forming apparatus 16 is connected with an apparatus control unit 72 made up of, e.g., a computer or the like, and controlled by the apparatus control unit 72. To be specific, the apparatus control unit 72 controls the bias power supply 46, the high frequency power supply 58 for generating the plasma, the variable DC power supply 64, the gas control unit 70, the throttle valve 24, the vacuum pump 26 and so forth so as to allow them to perform the following operations to carry out the thin film forming method in accordance with the present invention.

First, under the control of the apparatus control unit 72, by the operation of the gas control unit 70, the Ar gas is flown into the processing vessel 18 kept in a vacuum by the operation of the vacuum pump 26. Then, the throttle valve 24 is controlled so that the inside of the processing vessel 18 is maintained at a predetermined vacuum level. Then, the DC power is applied to the metal target 62 from the variable DC power supply 64, and the high frequency power (plasma power) is applied to the induction coil 56 via the high frequency power supply 58. Meanwhile, the apparatus control unit 72 sends an instruction to the bias power supply 46 so as to apply a predetermined bias power to the mounting table 28.

In the inside of the processing vessel 18 controlled as described above, argon plasma is generated by the plasma power applied to the induction coil 56, and resultantly argon ions are generated. These ions collide with the metal target 62. As a result, the metal target 62 is sputtered and metal particles are released.

Most of the metal atoms or metal atom groups, which are the metal particles released from the sputtered metal targets 62, are ionized while passing through the plasma. While the ionized metal ions and the electrically neutral metal atoms coexist in them, they are dispersed downward. Here, the pressure inside the processing vessel 18 is set to be of a relatively high level, e.g., about 50 mTorr or more. Therefore, the density of the plasma is increased, so that the metal particles can be ionized with high efficiency.

Then, the metal ions are introduced into an ion sheath region, which has a thickness of several millimeters (mm) on the surface of the wafer and is generated by the bias power applied to the mounting table 28. Then, the metal ions are attracted toward the wafer S so as to be accelerated with a strong directivity to be finally deposited on the wafer S. As for a thin film deposited by the metal ions having such a strong directivity as described, a coverage of a vertical shape can be obtained basically.

Here, each component of the apparatus is appropriately controlled by the apparatus control unit 72 based on a program created to enable the formation of the metal film to be carried out under predetermined conditions. Here, the program including instructions for controlling each component is stored in a storage medium 74 such as a floppy disc (registered trademark) (FD), a compact disc (registered trademark) (CD), a flash memory, a hard disc or the like, and each component is controlled to perform the process under the predetermined conditions based on the program.

Hereinafter, a method for forming a thin film in accordance with the present invention, which is performed by using the plasma film forming apparatus 16 configured as described above, will be explained.

The feature of the method of the present invention is to perform a prevention film forming process of forming a charging damage prevention film by a sputtering to prevent a charging damage on the surface of the semiconductor wafer as a pre-process of the thin film forming process for forming the thin film.

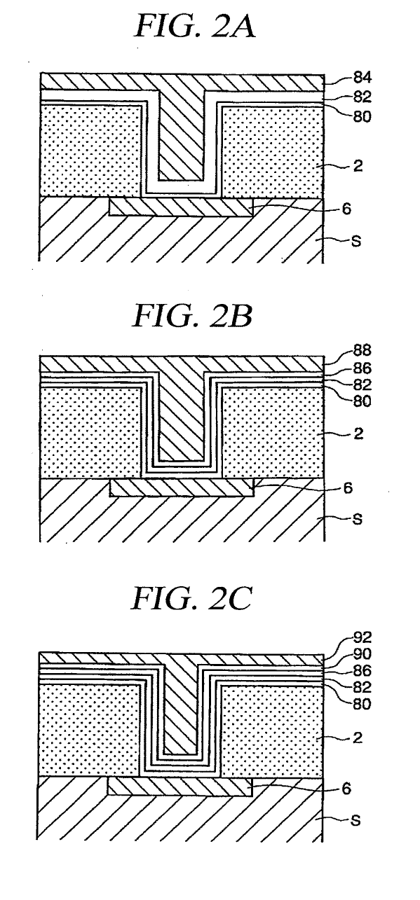

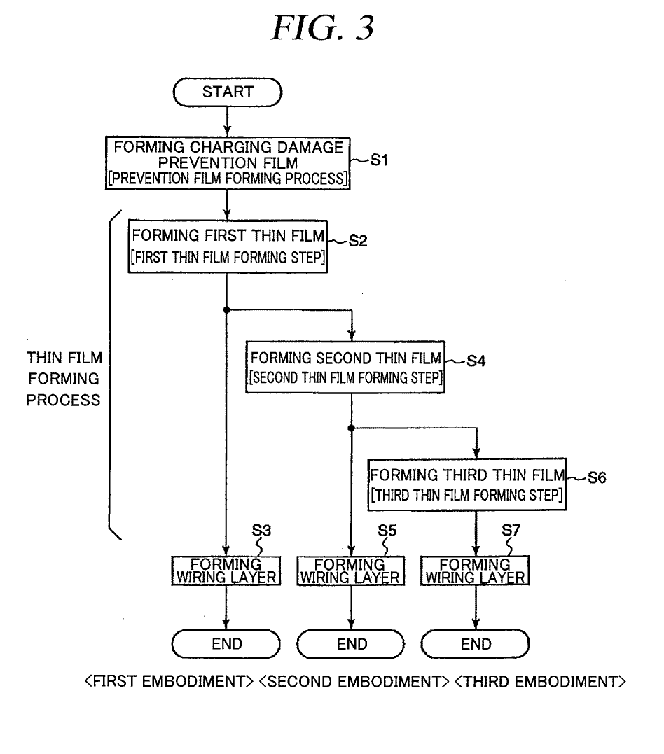

With reference to FIGS. 2A to 2C and FIG. 3, embodiments of the method of the present invention will be explained in detail hereinafter. FIGS. 2A to 2C provide cross sectional views to show examples of a thin film layered structure formed in accordance with each embodiment of the present invention. FIG. 3 is a flowchart for describing each embodiment of the present invention.

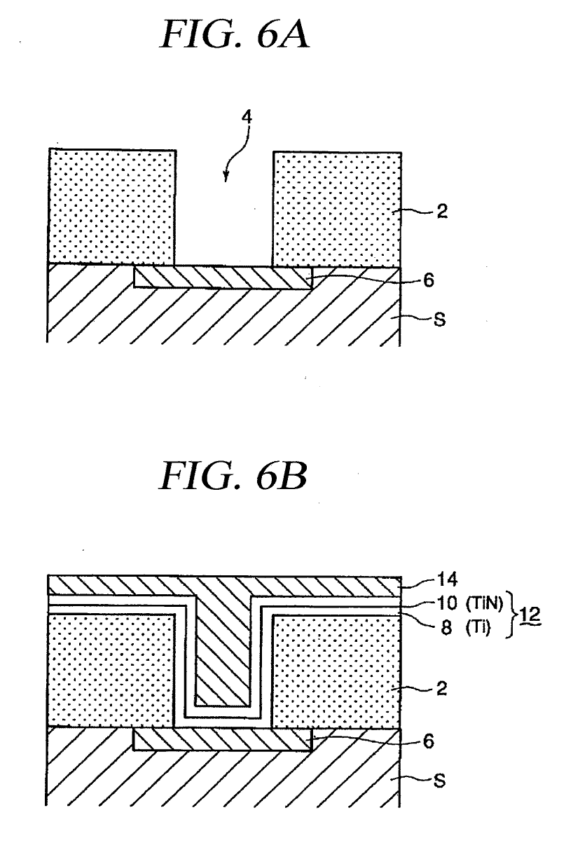

A wafer structure prior to the formation of the layered structure as illustrated in FIGS. 2A to 2C is the same as that illustrated in FIG. 6A. That is, as illustrated in FIG. 6A, an insulating layer 2 made up of, e.g., a SiO₂ film or the like is formed on a surface of a semiconductor wafer S, and a recess 4 of a hole shape such as a via hole, a through hole or a contact hole is formed in the insulating layer 2, and a contact portion 6 of an under layer to be electrically connected is exposed at a bottom portion of the recess 4. The contact portion 6 corresponds to a wiring layer in an under layer or an electrode of a device in the under layer, e.g., a source or a drain of a transistor, or the like.

Then, on a top surface of the wafer S having the above structure, various kinds of film forming processes are performed, whereby the layered structures as illustrated in FIGS. 2A to 2C are obtained. Here, first to third embodiments are illustrated. First, as illustrated in FIG. 3, the prevention film forming process (S1) is performed as the pre-process of the thin film forming process in all of the first to third embodiments. As a result, a charging damage prevention film 80 is formed by a sputtering. This prevention film 80 is formed not only on the surface of the insulating layer 2 of the wafer S but also on the entire inner surface of the recess 4 (see FIGS. 6A and 6B), that is, on the bottom and side surfaces thereof.

Subsequently, the thin film forming process is performed.

In the first embodiment, a first thin film element forming step (S2) is performed, so that a first thin film 82 is formed on the whole surface thereof by the sputtering (see FIG. 2A). Then, the inside of the recess 4 is filled, and a wiring layer 84 is formed on the whole surface thereof (S3). In this case, a single layer of the first thin film 82 serves as a barrier layer.

Meanwhile, in the second embodiment, after the first thin film 82 is formed on the whole surface by the sputtering, a second thin film element forming step (S4) is performed, so that a second thin film 86 is formed over the whole surface thereof, as illustrated in FIG. 2B. Then, the inside of the recess 4 is filled, and a wiring layer 88 is formed on the whole surface (S5). In this case, a layered structure of the first thin film 82 and the second thin film 86 serves as a barrier layer. Further, though the second thin film forming step (S4) can be performed by the sputtering process, it can also be performed by a thermal CVD process or a plasma CVD process.

Further, in the third embodiment, after the second thin film element forming step (S4) is performed to form the second thin film 86 over the whole surface, a third thin film element forming step (S6) is performed, and a third thin film 90 is formed over the whole surface, as illustrated in FIG. 2C. Further, the inside of the recess 4 is filled, and a wiring layer 92 is formed on the whole surface (S7). In this case, the layered structure of the first and second thin films 82 and 86 or a layered structure of the first to third thin films 82, 86 and 90 serves as a barrier layer. Further, though the third thin film element forming step (S6) can be performed by the sputtering process, it can also be performed by the thermal CVD process or the plasma CVD process. Further, when necessary, it may be also possible to form the wiring layer after further forming an additional thin film.

In the above-described first to third embodiments, the kinds of the thin films 82, 86 and 90 are different from one another. Each of these thin films 82, 86 and 90 is made of a metal film or a metal-containing film. A metal nitride film can be used as the metal-containing film. In case of forming the nitride film, it is possible to use, for example, an N₂ gas or the like as a nitriding gas. Further, when forming each of the thin films 82, 86 and 90 by the sputtering, it may be possible to use the plasma film forming apparatus 16 as illustrated in FIG. 1 in common, while replacing the metal target 62 depending on the kind of the formed film, or it may be possible to use different plasma film forming apparatuses 16 for each of the formed film so as to prevent different kinds of metal contaminations.

As described above, when the thin film 82 is formed on the surface of the semiconductor wafer S by the sputtering, it is possible to sharply reduce the occurrence of the charging damage during the sputtering because the charging damage prevention film 80 is formed by the sputtering in the pre-process.

Here, as the charging damage prevention film 80, it is possible to use one material selected from a group including Co (cobalt), Ge (germanium) and Ru (ruthenium). The charging damage prevention film 80 may have a thickness capable of obtaining a certain level of conductivity in a plane direction in order to prevent a charging damage from occurring in the first thin film 82 formed thereon. For example, it is desirable to have a thickness of a level of, e.g., several atomic layers: specifically, about 10 to 50 Å. In this manner, by forming the charging damage prevention film 80 to have such a thin thickness, it is possible to minimize an increase of a wiring resistance even if the charging damage prevention film 80 is formed of a material with a higher electrical resistance than that of the wiring layers 84, 88 and 92 formed thereon. Further, even when the wiring layers 84, 88 and 92 are etched, it is possible to etch the charging damage prevention film 80 under the same process conditions as those for the etching of the wiring layers 84, 88 and 92.

In addition, if the thickness of the charging damage prevention film 80 is bigger than about 50 Å, the wiring resistance may be increased or there may occur a problem when etching the wiring layer. Meanwhile, if the thickness of the charging damage prevention film 80 is smaller than about 10 Å, it is impossible to fully suppress the occurrence of the charging damage.

Further, when the charging damage prevention film 80 is formed by the prevention film forming process, it is desirable to set a sputtering yield to be in the range of about 0.9 to 1.1 atoms/ion. This is because if the sputtering yield is within such range, the amounts of the atoms and the ions generated during the sputtering are balanced, so that it becomes difficult for a charge-up to occur due to an unbalance in the charges which are charged during the film formation, and an electrically neutral state is obtained. In other words, if the sputtering yield is out of the specified range, the charging damage prevention film 80 itself becomes vulnerable to a charging damage while it is being formed. For reference, the sputtering yield indicates an easiness to be sputtered in numbers. The sputtering yield depends on the ion energy (eV) and the kind of the rare gas supplied during the plasma generation. The ion energy (eV) depends on a voltage applied to the metal target 62 by the DC power supply 64 of FIG. 1.

An example of a sputtering yield for each ion is described in Chapter 8 (pages from 257 to 258) of “Vacuum Handbook, New Edition” (Ohmsha, edited by ULVAC, Inc., published in August 2002). For example, if the ion energy is about 400 eV, a material having a sputtering yield within the range from about 0.9 to 1.1 atoms/ion and having a low possibility of metal contamination, e.g., Co, Ge, Ru or the like, can be selected as a material for forming the charging damage prevention film 80.

Further, if the charging damage prevention film 80 is formed first as a base film, even if a metal film highly likely to incur the charging damage, such as an Al film (including an Al alloy), a W (tungsten) film, a Cu (copper) film, a Ti (titan) film and a Ta (tantalum) film or a metal nitride film such as a TiN film, a TaN film or the like, is formed on the charging damage prevention film 80 by the sputtering, the charged charges may be dispersed via the conductive charging damage prevention film 80 located below. That is, the charging damage is never incurred.

Hereinafter, each embodiment will be explained in more detail. In the first embodiment illustrated in FIG. 2A, a Co film may be used as the charging damage prevention film 80; a TiN film may be used as the first thin film 82; and an Al layer or a W layer may be used as the wiring layer 84. Further, the Al layer includes an Al alloy film such as an Al alloy layer containing Cu. In such case, the TiN film serves as a barrier layer. Further, in this case, at least the charging damage prevention film 80 and the TiN film serving as the first thin film 82 are formed by the sputtering.

Further, in the second embodiment illustrated in FIG. 2B, a Co film may be used as the charging damage prevention film 80; a Ti film may be used as the first thin film 82; a TiN film may be used as the second thin film 86; and an Al layer or a W layer may be used as the wiring layer 88. Further, the Al layer includes an Al alloy film such as an Al alloy layer containing Cu. In this case, a layered structure of the Ti film and the TiN film serves as a barrier layer. Further, in this case, at least the charging damage prevention film 80 and the Ti film serving as the first thin film 82 are formed by the sputtering.

Further, in the third embodiment illustrated in FIG. 2C, a Co film may be used as the charging damage prevention film 80; a TaN film may be used as the first thin film 82; a Ta film may be used as the second thin film 86; a Cu film to become a seeding film may be used as the third thin film; and a Cu layer may be used as the wiring layer 92. Further, in this case, a layered structure of the TaN film and the Ta film serves as a barrier layer. Further, in this case, at least the charging damage prevention film 80 and the TaN film serving as the first thin film 82 are formed by the sputtering. Further, the third thin film 86 is a seeding film made up of a thin Cu film formed by the sputtering. The wiring layer 92 formed of a Cu layer is formed starting from this seeding film by the electroplating.

The layered structure in each embodiment is nothing more than an example. That is, the present invention is not limited to the above-described layered structure in each embodiment.

<Experiment for Confirming the Effects of the Present Invention>

An experiment for confirming the above-described effects of the present invention was carried out, and the evaluation result thereof will be explained hereinafter.

In the experiment, a thin-film layered structure in accordance with the first embodiment as illustrated in FIG. 2A was formed on a semiconductor wafer. To elaborate, a Co film was formed as the charging damage prevention film 80 by the sputtering, and thereon, a TiN film was formed as the first thin film 82 by the sputtering. After the TiN film was formed, a leakage current of the TiN film was measured. Here, the Co film serving as the charging damage prevention film 80 has a thickness of about 10 to 30 Å. Further, the TiN film serving as the first thin film 82 has a thickness of about 300 Å. Further, as the semiconductor wafer on which the film formation is performed, a special planar antenna substrate was used in order to measure a resistance against the charge-up. The antenna ratio (S1/S2) of this planar antenna substrate was about 10⁶. This planar antenna substrate is a so-called “TEG” (the antenna structure thereof is illustrated in FIG. 5).

In this experiment, the wiring layer 84 was not formed. It is because the generation of the charging damage as a whole only depends on whether or not the charging damage is incurred in the first thin film 82 formed directly on the charging damage prevention film 80, so that it is not necessary to form the wiring layer 84 for the measurement.

Further, in a comparative example, a TiN film was directly formed by the sputtering without forming a Co film.

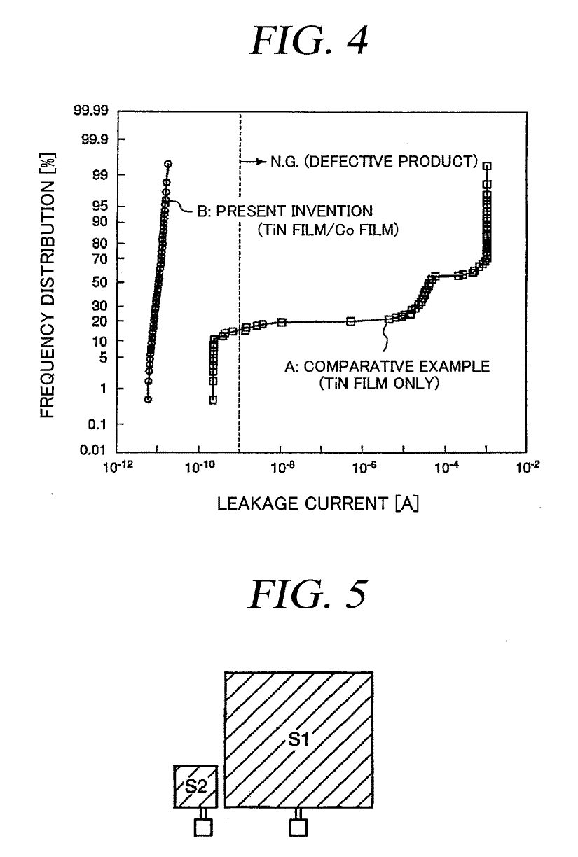

FIG. 4 is a graph showing an occurrence or non-occurrence of the charging damage, wherein the horizontal axis represents a leakage current and the vertical axis represents a frequency distribution. In FIG. 4, a curve A corresponds to the film structure made up of the TiN film in accordance with the comparative example, while a curve B corresponds to the film structure made up of the TiN film/Co film in accordance with the method of the present invention. If the leakage current of a product is about 10⁻⁹ A or greater, the product is regarded as N.G. (No Good), i.e., as a defective product.

As illustrated in FIG. 4, the comparative example corresponding to the curve A is not desirable since a ratio of good product is just about 15%, while a ratio of defective product reaches about 85%. On the contrary, the method of the present invention corresponding to the curve B shows a desirable result with the ratio of good product of 100% and the ratio of defective product of 0%.

Besides, it could also be confirmed that the same effects as those obtained with the TiN film or even higher effects can be obtained when forming the TiN film having a good conductivity or when forming the TaN film as the first thin film 82.

Further, though the semiconductor wafer is exemplified as the target object in the above description, the present invention is not limited thereto, but can also be applied to a glass substrate, an LCD substrate, a ceramic substrate, or the like.

What is claimed is:

1. A thin film forming method comprising:
a prevention film forming process for forming a charging damage prevention film for preventing a charging damage on a surface of a target object by a sputtering; and
a thin film forming process for forming a desired thin film on a surface of the charging damage prevention film, which is formed on the surface of the target object, by a sputtering.

2. The method of claim 1, wherein the charging damage prevention film is made of one of Co (cobalt), Ge (germanium) and Ru (ruthenium).

3. The method of claim 1, wherein, on the surface of the target object, an insulating layer is formed in advance, and
in the prevention film forming process, the charging damage prevention film for preventing the charging damage is formed on a surface of the insulating layer.

4. The method of claim 1, wherein, in the thin film forming process, one kind of thin film is formed.

5. The method of claim 1, wherein, in the thin film forming process, a plurality of different kinds of thin films is formed in sequence.

6. The method of claim 1, wherein the thin film is a metal film or a metal-containing film.

7. A layered structure of thin films formed on a surface of a target object, the structure comprising:
a charging damage prevention film formed on the surface of the target object by a sputtering; and
a single-layered thin film formed on a surface of the charging damage prevention film by a sputtering.

8. The layered structure of claim 7, wherein the single-layered thin film is made of a TiN film.

9. The layered structure of claim 8, wherein the TiN film constitutes a barrier layer.

10. The layered structure of claim 9, wherein, on the TiN film, a wiring layer is formed.

11. The layered structure of claim 10, wherein the wiring layer is made of one of an Al (including an Al alloy) film, a W film and a Cu film.

12. A layered structure of thin films formed on a surface of a target object, the structure comprising:
a charging damage prevention film formed on the surface of the target object by a sputtering; and
a plurality of thin film elements formed on a surface of the charging damage prevention film by a sputtering.

13. The layered structure of claim 12, wherein the plurality of thin film elements are of different kinds from one another.

14. The layered structure of claim 13, wherein the plurality of thin film elements are made of a Ti film element in a lower layer and a TiN film element in an upper layer.

15. The layered structure of claim 13, wherein the plurality of thin film elements are made of a TaN film element in a lower layer and a Ta film element in an upper layer.

16. The layered structure of claim 12, wherein the plurality of thin film elements constitute a barrier layer.

17. The layered structure of claim 16, wherein, on the plurality of thin film elements, a wiring layer is formed.

18. The layered structure of claim 17, wherein the wiring layer is made of one of an Al (including an Al alloy) film, a W film and a Cu film.
